(19) United States
(12) Patent Application Publication
(10) Pub. No.: US 2010/0090871 A1
(43) Pub. Date: Apr. 15, 2010

(54) KEYSWITCH AND KEYBOARD

(76) Inventors: Liang-Ta Yeh, Shulin City (TW); Chao-Lung Chang, Jhunan Township (TW)

Correspondence Address: PATTERSON & SHERIDAN, LLP - - - IPTEC, 3040 Post Oak Boulevard, Suite 1500, Houston, TX, 77056-6582, US

(21) Appl. No.: 12/575,279

(22) Filed: Oct. 7, 2009

(30) Foreign Application Priority Data
Oct. 9, 2008 (TW) 097218179

(51) Int. Cl. H03M 11/00

(52) U.S. Cl. 341/22

(57) ABSTRACT

The invention discloses a keyswitch and a keyboard. The keyboard includes a base plate assembly and a plurality of keyswitches. The base plate assembly includes a first base plate and a second base plate. The second base plate is riveted to the first base plate. Each keyswitch includes a keyswitch module. Each keyswitch module is pivotally connected on the base plate assembly. The first base plate includes a hole. The circumference of the hole forms a protrusion structure. When the second base plate is riveted to the first base plate via the hole, the protrusion structure will be compressed and inserted in the second base plate tightly.

### BACKGROUND OF THE INVENTION

1. Field of the Invention

The invention relates to a keyswitch and keyboard, and particularly, the invention relates to the keyswitch and keyboard having a base plate assembly with a protrusion structure design. When the second base plate and the first base plate of the base plate assembly are riveted to each other, the protrusion structure can make the first base plate and the second base plate of the base plate assembly to be tightly riveted to each other.

2. Description of the Prior Art

With the electronic technique being well developed these days, various electronic devices, such as computer, server, portable communicating device, and etc., become popular on market. Because of the precise design of the electronic device for the requirement of the multifunctional, the space utility in the electronic device for economic benefits becomes an important issue to industry. Therefore, the assembling function on various types of electronic devices is very significant.

The used assembling way in industry at present is nothing more than machining ways such as screwing, welding, and riveting for assembling two work pieces. The traditional riveting structure includes a riveting receiving component and a riveting component protruding from the riveting receiving component. The riveting receiving component has a hole corresponding to the riveting component for the pass of the riveting head of the riveting component, where the diameter of the riveting head is larger than the diameter of the hole. When the main body of the riveting head passes through the hole and protrudes to a side of the riveting receiving component, the riveting head leans against another side of the riveting receiving component. The riveting head could be applied with an external force to make the riveting head to become deformed, so that the riveting head could be buried in the riveting receiving component to fix the riveting component on the riveting receiving component. The main body of the riveting component protruding from the riveting receiving component could further connect with a work piece, so as to fix the work piece on the riveting receiving component.

As the example of the electronic device of the server, the metal plates forming the casing mainly utilize the riveting components, which passes through the holes of the metal plates, such as rivets to connect with each other. Please refer to FIG. 1A and FIG. 1B. FIG. 1A is a schematic diagram illustrating that the metal plates are stacked with each other at the riveting place after riveting in the prior art. FIG. 1B is a cross-sectional view illustrating the metal plates in FIG. 1A. As shown in FIG. 1A and FIG. 1B, in the design of the casing of the server, two metal plates 10 are stacked with each other and the holes 100 of each of the metal plates 10 are aligned to each other for the riveting work by the riveting components such as the rivets, wherein the metal plate 10 is a plate structure of plane type and the hole 100 is a hole structure of plane type formed by the way such as drilling.

Besides, as the example of the electronic device of the keyboard, one of the metal plates forming the substrate is regarded as the riveting component and is deformed to pass through the hole of the other metal plate for the riveting work. Please refer to FIG. 2A and FIG. 2B. FIG. 2A is a cross-sectional view illustrating the traditional metal plates before riveting in the prior art. FIG. 2B is a cross-sectional view illustrating the metal plates in FIG. 2A after riveting. As shown in FIG. 2A and FIG. 2B, in the substrate design of the keyboard, the first metal plate 20 and the second metal plate 22 are stacked with each other, and the part, which is located at the position corresponding to the hole 220 of the second metal plate 22, of the first metal plate 20 is compressed and deformed toward the hole 220 for the riveting work, wherein the first metal plate 20 and the second metal plate 22 are a plate structure of plane type and the hole 220 of the second metal plate is a hole structure of plane type formed by the way such as drilling.

However, although the above-mentioned hole structures have benefit of convenient processes, them fail in the reliability of the electronic devices required in the present days. The two metal plates have surface contacts on the perpendicular direction relative to the surfaces for ensuring that the construction could bear a large pulling force and pressing force. However, on the horizontal direction, the construction only ensures the strength via the point contacts at the riveting place, and it is obvious that the point contact structure could not bear a large force on the horizontal direction. If the electronic device is shaken on the horizontal direction, the connecting component might not bear the stress of the metal plates and might fall off to make the connecting point being loose, and even the connecting component might be broken by twisting.

Furthermore, if the riveting place is forced by a radial force to sway, the metal plates are worn down because of the rubbing caused by the swaying, so that the size of the riveting component would be reduced and the riveting component would be deformed. Oppositely, the size of the hole would be increased and the hole would be deformed because the metal plates are worn down or deformed. The result above-mentioned makes the pressing force between the riveting component and the hole to disappear and makes the situation that riveting component falls off from the riveting receiving component to occur.

Therefore, the major scope of the invention is to provide a keyswitch and a keyboard. The keyboard includes a strengthened base plate assembly for carrying the keyswitch. The base plate assembly includes a first base plate and a second plate riveted to the first base plate. Particularly, according to the protrusion structure configured on the base assembly of the invention, the protrusion structure could be compressed and inserted tightly into the first base plate or the second base plate when the second base plate is riveted to the first base plate. Accordingly, the problem that the riveting place could not bear a large force on the horizontal direction could be solved and the riveting component could be prevented from falling off from the riveting receiving component.

### SUMMARY OF THE INVENTION

A scope of the invention is to provide a keyswitch including a base plate assembly and a keyswitch module. The base plate assembly includes a first base plate and a second base plate riveted to the first base plate. The keyswitch module is pivotally connected to the base plate assembly, and particularly, the first base plate further includes a hole. The circumference of the hole forms a protrusion structure. When the second base plate is riveted to the first base plate through the hole, the protrusion structure is compressed and inserted tightly in the second base plate.

Another scope of the invention is to provide a keyboard including a base plate assembly and a plurality of keyswitches. The base plate assembly includes a first base plate and a second base plate riveted to the first base plate. Each of the plurality of keyswitches includes a keyswitch module pivotally connected on the base plate assembly. Particularly, the first base plate further includes a hole. The circumference of the hole forms a protrusion structure. When the second base plate is riveted to the first base plate through the hole, the protrusion structure is compressed and inserted tightly into the second base plate.

Therefore, according to the keyswitch and the keyboard of the invention, the keyboard, the keyboard includes a strengthened base plate assembly for carrying the keyswitch. The base plate assembly includes a first base plate and a second plate riveted to the first base plate. Particularly, according to the protrusion structure configured on the base assembly of the invention, the protrusion structure could be compressed and inserted tightly into the first base plate or the second base plate tightly when the second base plate is riveted to the first base plate. Accordingly, the problem that the riveting place could not bear a large force on the horizontal direction could be solved and the riveting component could be prevented from falling off from the riveting receiving component.

The advantage and spirit of the invention may be understood by the following recitations together with the appended drawings.

### BRIEF DESCRIPTION OF THE APPENDED DRAWINGS

FIG. 1A is a schematic diagram illustrating that the metal plates are stacked with each other at the riveting place after riveting in the prior art.

FIG. 1B is a cross-sectional view illustrating the metal plates in FIG. 1A.

FIG. 2A is a cross-sectional view illustrating the traditional metal plates before riveting in the prior art.

FIG. 2B is a cross-sectional view illustrating the metal plates in FIG. 2A after riveting.

FIG. 3 is an appearance view illustrating the keyboard according to an embodiment of the invention.

FIG. 4 is a cross-sectional view illustrating the keyswitch according to an embodiment of the invention.

FIG. 5A is a cross-sectional view illustrating a first embodiment of the base plate assembly of the keyswitch in FIG. 4, wherein the first base plate is not riveted to the second base plate yet.

FIG. 5B is a cross-sectional view illustrating the base plate assembly in FIG. 5A, wherein the first base plate and the second base plate are riveted to each other.

FIG. 6 is a cross-sectional view illustrating the keyswitch according to another embodiment of the invention.

FIG. 7A is a cross-sectional view illustrating a second embodiment of the base plate assembly of the keyswitch in FIG. 6, wherein the first base plate is not riveted to the second base plate yet.

FIG. 7B is a cross-sectional view illustrating the base plate assembly in FIG. 7A, wherein the first base plate and the second base plate are riveted to each other.

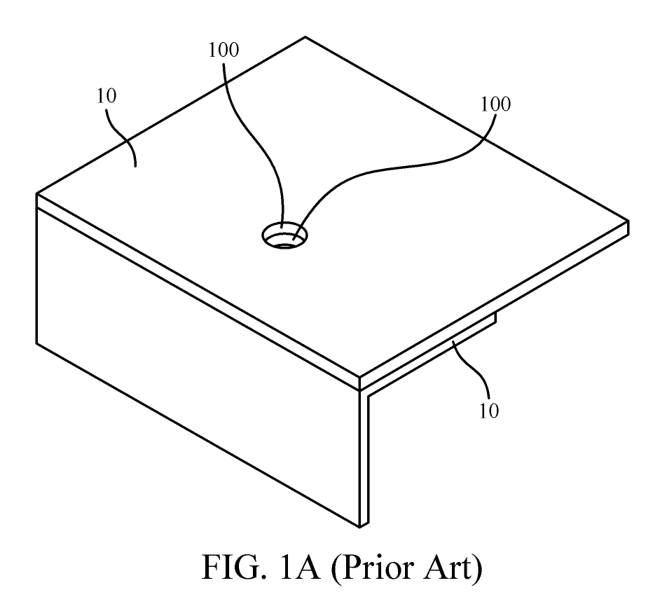

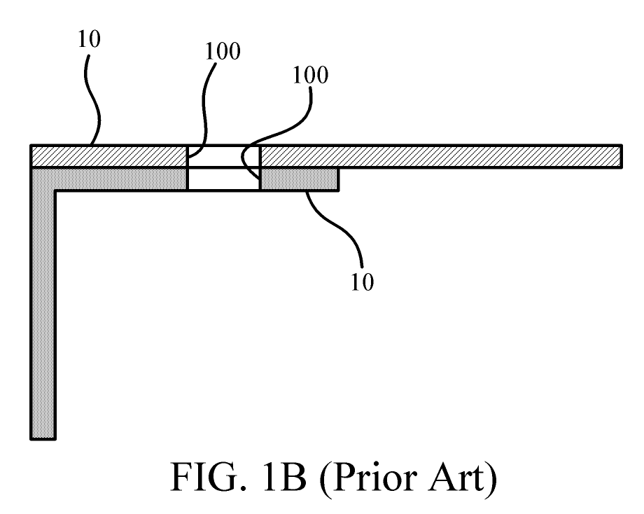

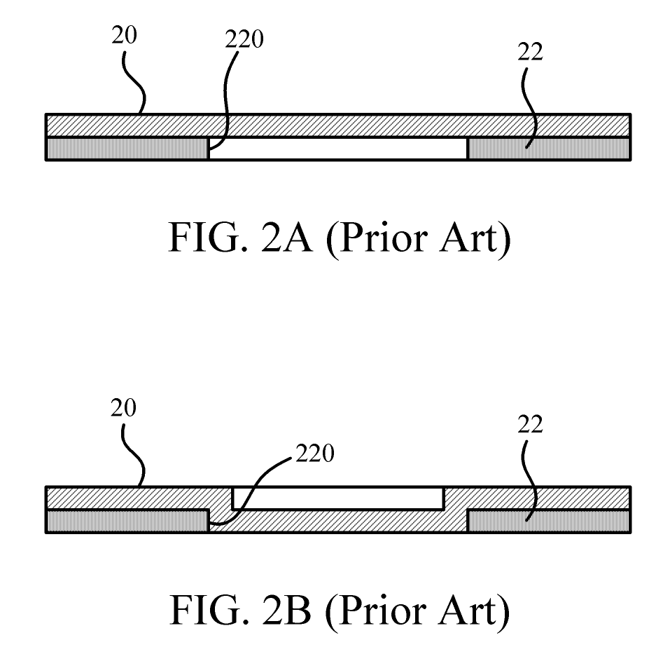

### DETAILED DESCRIPTION OF THE INVENTION

The invention is to provide a keyswitch and a keyboard, and particularly, the base plate assembly thereof has a protrusion structure capable of assisting the first base plate and the second plate to be riveted tightly.

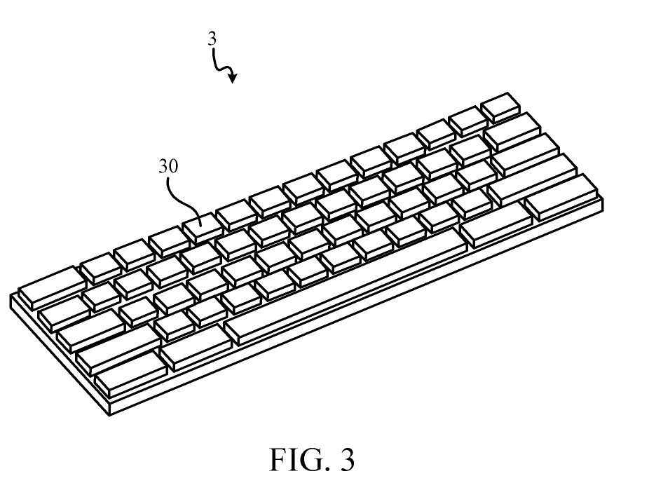

Please refer to FIG. 3. FIG. 3 is an appearance view illustrating the keyboard 3 according to an embodiment of the invention. As shown in FIG. 3, the keyboard 3 includes a plurality of keyswitches 30. The construction, function, and motion of keyswitches 30 would be described in detail in the following.

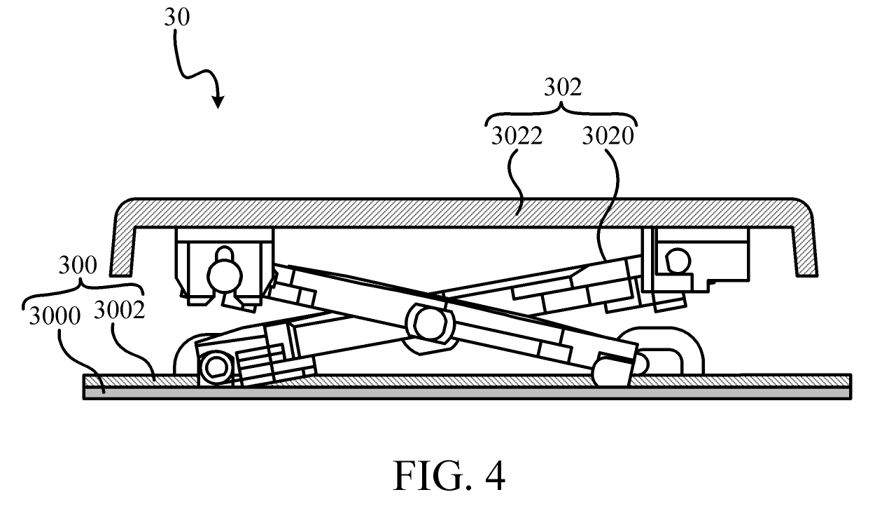

Please refer to FIG. 4. FIG. 4 is a cross-sectional view illustrating the keyswitch 30 in FIG. 3. As shown in FIG. 4, the keyswitch 30 includes a base plate assembly 300 and a keyswitch module 302. The keyswitch module 302 includes a scissors-like supporting member 3020 and a keycap 3022. The scissors-like supporting member 3020 is pivotally connected to the base plate assembly 300, and similarly, the keycap 3022 is pivotally connected to the scissors-like supporting member 3020.

It should be noted that for the keyboard 3 to support the plurality of keyswitch modules 302 sufficiently, the base plate assembly 300, located under each keyswitch module 302, with a quite thickness is traditionally made of high hardness metal material and made. However, it might not meet the requirement of market for the electronic product to be light and portable in the present days.

Therefore, according to the embodiment of the invention, the base plate assembly 300 under each of the keyswitch modules 302 of the keyboard 3 includes a first base plate 3000 and the second base plate 3002. The second base plate 3002 could be assembled to the first base plate 3000 by riveting. In this embodiment, the first base plate 3000 could be made of a first metal material and the second base plate 3002 could be made of a second metal material, wherein the first metal material is harder than the second metal material.

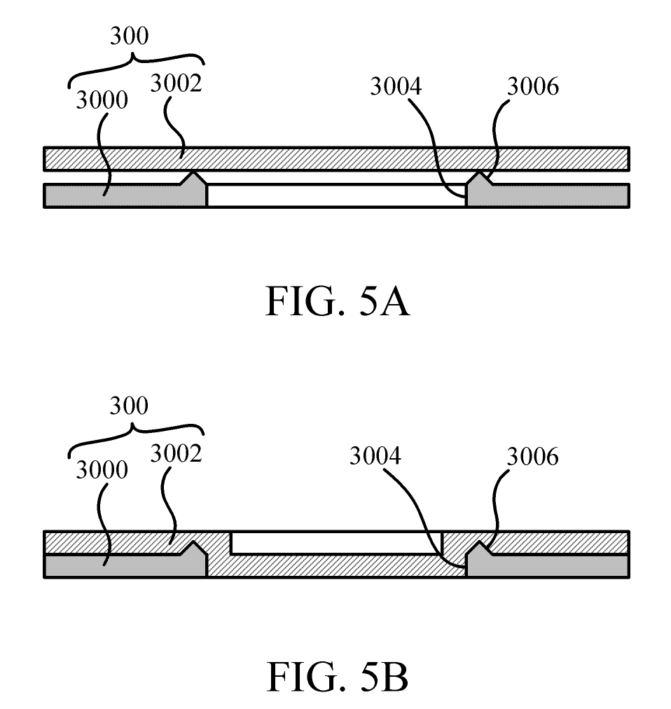

Please refer to FIG. 5A. FIG. 5A is a cross-sectional view illustrating a first embodiment of the base plate assembly 300 of the keyswitch 30 in FIG. 4, wherein the first base plate 3000 is not riveted to the second base plate 3002 yet. As shown in FIG. 5A, the first base plate 3000 could further include a hole 3004 and the circumference of the hole 3004 could form a protrusion structure 3006.

In practice, the burr of the hole 3004 could be controlled in the punching process of the hole 3004 to obtain an irregular protrusion structure 3006 on the circumference of the hole 3004 of the first base plate 3000, however, it is not a limitation for generating the protrusion structure 3006. On the other hand, the shape of the protrusion structure 3006 on the circumference of the hole 3004 of the first base plate 3000 could be designed as regular sharp bulges (such as nails) around the circumference of the hole 3004, and it could also strengthen the base plate assembly 300 for supporting each of the keyswitch modules 302 of the keyboard 3 when the first base plate 3000 and the second base plate 3002 are riveted to each other.

Please refer to FIG. 5B. FIG. 5B is a cross-sectional view illustrating the base plate assembly 300 in FIG. 5A, wherein the first base plate 3000 and the second base plate 3002 are riveted to each other. As the description above-mentioned, the first metal material is harder than the second metal material, so the second base plate 3002 made of the second metal material with smaller hardness is compressed to the first bas plate 3000 made of the first metal material with larger hardness during the riveting process. In other words, when the second base plate 3002 is riveted to the first base plate 3000 through the hole 3004 of the first base plate 3000, the protrusion structure 3006 of the first base plate 3000 could be compressed and inserted in the second base plate 3002 tightly. Accordingly, it could also strengthen the base plate assembly 300 for supporting each of the keyswitch modules 302 of the keyboard 3 by riveting the first base plate 3000 and the second base plate 3002.

Please refer to FIG. 4. It is obvious that the keyswitch module 302 could be pivotally connected to the second base plate 3002 of the base plate assembly 300 directly because the second base plate 3002 is above the first base plate 3000 of the base plate assembly 300, however, it is not a limitation. Oppositely, the keyswitch module 302 could be pivotally connected to the first base plate 3000 through the passing hole (not shown in the figures) formed at the location, correspondingly to the pivotally connecting place between the keyswitch module 302 and the first base plate 3000, of the second base plate 3002 in practice.

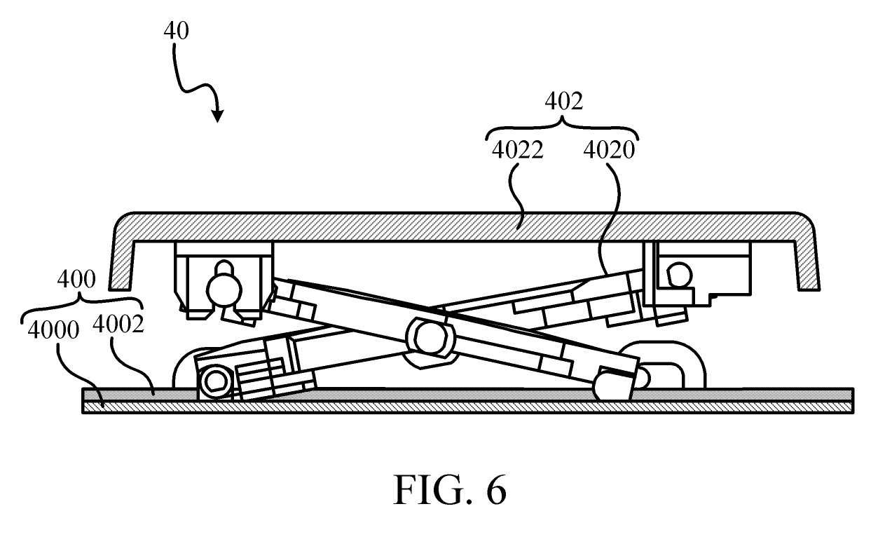

Please refer to FIG. 6. FIG. 6 is a cross-sectional view illustrating the keyswitch 40 according to another embodiment of the invention. The keyboard 3 in the last embodiment could include a plurality of the keyswitch 40. As shown in FIG. 6, the keyswitch 40 includes a base plate assembly 400 and a keyswitch module 402. Similarly, the keyswitch module 402 includes a scissors-like supporting member 4020 and a keycap 4022. The scissors-like supporting member 4020 is pivotally connected to the base plate assembly 400, and similarly, the keycap 4022 is pivotally connected to the scissors-like supporting member 4020.

Similarly, for the keyboard 3 to support the plurality of keyswitch modules 402 sufficiently, according to the embodiment of the invention, the base plate assembly 400 under each of the keyswitch modules 402 of the keyboard 3 includes a first base plate 4000 and the second base plate 4002. The second base plate 4002 could be assembled to the first base plate 4000 by riveting. In this embodiment, the first base plate 4000 could be made of a second metal material and the second base plate 4002 could be made of a first metal material, wherein the first metal material is harder than the second metal material.

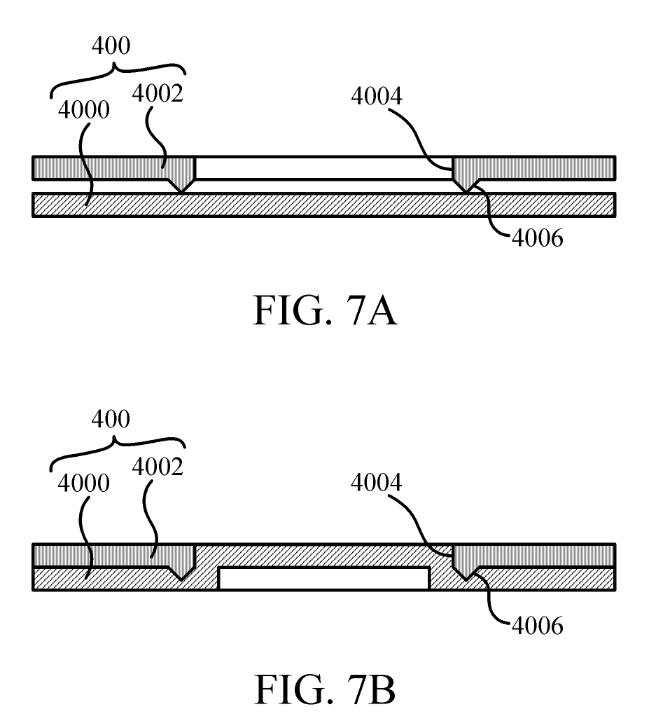

Please refer to FIG. 7A. FIG. 7A is a cross-sectional view illustrating a second embodiment of the base plate assembly 400 of the keyswitch 40 in FIG. 6, wherein the first base plate 4000 is not riveted to the second base plate 4002 yet. As shown in FIG. 7A, the second base plate 4002 could further include a hole 4004 and the circumference of the hole 4004 could form a protrusion structure 4006.

In practice, the burr of the hole 4004 could be controlled in the punching process of the hole 4004 to obtain an irregular protrusion structure 4006 on the circumference of the hole 4004 of the second base plate 4002, however, it is not a limitation for generating the protrusion structure 4006. On the other hand, the shape of the protrusion structure 4006 on the circumference of the hole 4004 of the second base plate 4002 could be designed as regular sharp bulges (such as nails) around the circumference of the hole 4004, and it could also strengthen the base plate assembly 400 for supporting each of the keyswitch modules 402 of the keyboard 3 when the first base plate 4000 and the second base plate 4002 are riveted to each other.

Please refer to FIG. 7B. FIG. 7B is a cross-sectional view illustrating the base plate assembly 400 in FIG. 7A, wherein the first base plate 4000 and the second base plate 4002 are riveted to each other. As the description above-mentioned, the first metal material is harder than the second metal material, so the first base plate 4000 made of the second metal material with smaller hardness is compressed to the second bas plate 4002 made of the first metal material with larger hardness during the riveting process. In other words, when the first base plate 4000 is riveted to the second base plate 4002 through the hole 4004 of the second base plate 4002, the protrusion structure 3006 of the second base plate 4002 could be compressed and inserted in the first base plate 4000 tightly. Accordingly, it could also strengthen the base plate assembly 400 for supporting each of the keyswitch modules 402 of the keyboard 3 by riveting the first base plate 4000 and the second base plate 4002.

Please refer to FIG. 6. It is obvious that the keyswitch module 402 could be pivotally connected to the second base plate 4002 of the base plate assembly 400 directly because the second base plate 4002 is above the first base plate 4000 of the base plate assembly 400, however, it is not a limitation. Oppositely, the keyswitch module 402 could be pivotally connected to the first base plate 4000 through the passing hole (not shown in the figures) formed at the location, correspondingly to the pivotally connecting place between the keyswitch module 402 and the first base plate 4000, of the second base plate 4002 in practice.

In an embodiment, because the first metal material is harder than the second metal material, the first metal material could be a stainless steel material or a Steel-Electrogalvanized-Coldrolled-Coid (SECC) material, and the second metal material could be an aluminum material. However, it is not a limitation.

As described in the above embodiments, it is obvious that the keyboard of the invention includes a strengthened base plate assembly for carrying the keyswitches. The base plate assembly includes a first base plate and a second plate riveted to the first base plate. Particularly, according to the protrusion structure configured on the base assembly of the invention, the protrusion structure could be compressed and inserted tightly into the first base plate or the second base plate tightly when the second base plate is riveted to the first base plate. Accordingly, the problem that the riveting place could not bear large force on the horizontal direction could be solved and the riveting component could be prevented from falling off from the riveting receiving component.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A keyswitch, comprising:
a base plate assembly, comprising:
a first base plate; and
a second base plate, riveted to the first base plate; and
a keyswitch module, pivotally connected to the base plate assembly.

2. The keyswitch of claim 1, wherein the first base plate is made of a first metal material and the second base plate is made of a second metal material, and the first metal material is harder than the second metal material.

3. The keyswitch of claim 2, wherein the first base plate further comprises a hole, and the circumference of the hole forms a protrusion structure, when the second base plate is riveted to the first base plate via the hole, the protrusion structure is compressed and inserted in the second base plate tightly.

4. The keyswitch of claim 2, wherein the first metal material is a stainless steel material or a Steel-Electrogalvanized-Coldrolled-Coid (SECC) material, and the second metal material is an aluminum material.

5. The keyswitch of claim 1, wherein the first base plate is made of a second metal material and the second base plate is made of a first metal material, and the first metal material is harder than the second metal material.

6. The keyswitch of claim 5, wherein the second base plate further comprises a hole, and the circumference of the hole forms a protrusion structure, when the first base plate is riveted to the second base plate via the hole, the protrusion structure is compressed and inserted in the first base plate tightly.

7. The keyswitch of claim 5, wherein the first metal material is a stainless steel material or a Steel-Electrogalvanized-Coldrolled-Coid (SECC) material, and the second metal material is an aluminum material.

8. The keyswitch of claim 1, wherein the keyswitch module is pivotally connected to the first base plate.

9. The keyswitch of claim 1, wherein the keyswitch module is pivotally connected to the second base plate.

10. A keyboard, comprising:
a base plate assembly, comprising:
a first base plate; and
a second base plate, riveted to the first base plate; and
a plurality of keyswitches, each of the keyswitches comprising:
a keyswitch module, pivotally connected to the base plate assembly.

11. The keyboard of claim 10, wherein the first base plate is made of a first metal material and the second base plate is made of a second metal material, and the first metal material is harder than the second metal material.

12. The keyboard of claim 11, wherein the first base plate further comprises a hole, and the circumference of the hole is formed a protrusion structure, when the second base plate is riveted to the first base plate via the hole, the protrusion structure is compressed and inserted in the second base plate tightly.

13. The keyboard of claim 11, wherein the first metal material is a stainless steel material or a Steel-Electrogalvanized-Coldrolled-Coid (SECC) material, and the second metal material is an aluminum material.

14. The keyboard of claim 10, wherein the first base plate is made of a second metal material and the second base plate is made of a first metal material, and the first metal material is harder than the second metal material.

15. The keyboard of claim 14, wherein the second base plate further comprises a hole, the circumference of the hole is formed a protrusion structure, when the first base plate is riveted to the second base plate via the hole, the protrusion structure is compressed and inserted in the first base plate tightly.

16. The keyboard of claim 14, wherein the first metal material is a stainless steel material or a Steel-Electrogalvanized-Coldrolled-Coid (SECC) material, and the second metal material is an aluminum material.

17. The keyboard of claim 10, wherein the keyswitch module is pivotally connected to the first base plate.

18. The keyboard of claim 10, wherein the keyswitch module is pivotally connected to the second base plate.
